(19) United States
(12) Patent Application Publication
(10) Pub. No.: US 2007/0099424 A1
(43) Pub. Date: May 3, 2007

(54) Reduction of mechanical stress on pattern specific geometries during etch using double pattern layout and process approach

(75) Inventors: Benjamen Michael Rathsack, Richardson, TX (US); James Walter Blatchford, Richardson, TX (US); Steven Arthur Vitale, Murphy, TX (US)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 11/260,239

(22) Filed: Oct. 28, 2005

(51) Int. Cl. C23F 1/00; H01L 21/302

(52) U.S. Cl. 438/689; 216/41

(57) ABSTRACT

According to various embodiments, methods to eliminate high stress areas in a mask during a gate trim etch are provided. High stress areas can include, for example, gate regions that are anchored at only one end. The exemplary methods can include the use of a double pattern layout, for example, separating printing and etching of a pattern specific geometry in the mask into two or more portions.

### DESCRIPTION OF THE INVENTION

1. Field of the Invention

The present invention relates to semiconductor devices and methods for their fabrication. More particularly, the present invention relates to methods for reducing errors in a patterned mask due to mechanical stress during fabrication of semiconductor devices.

2. Background of the Invention

Lithographic projection apparatus (tools) can be used, for example, in the manufacture of integrated circuits (ICs). When using the various tools, a mask can be used that contains a circuit pattern corresponding to an individual layer of the IC, and this pattern can be imaged onto a target portion (e.g., comprising one or more dies) on a substrate, such as a silicon or other wafer comprising a semiconductor, that has been coated with a layer of radiation-sensitive material, such as a resist.

The masks comprise geometric patterns corresponding to the circuit components to be integrated onto a substrate. The patterns used to create such masks are typically generated using computer-aided design (CAD) programs, sometimes called electronic design automation (EDA). Most CAD programs follow a set of predetermined design rules in order to create functional masks. These rules are set by processing and design limitations. For example, design rules can define the space tolerance between circuit devices, such as gates, capacitors, etc., or interconnect lines, so as to ensure that the circuit devices or lines do not interact with one another in an undesirable way.

One of the goals in IC fabrication is to faithfully reproduce the original circuit design or “layout” on the wafer using the mask. Another goal is to use as much of the wafer real estate as possible. As the size of an IC is reduced and its density increases, however, the critical dimension (CD) of its corresponding mask pattern approaches the resolution limit of the optical exposure tool. The resolution for an exposure tool can be defined as the minimum feature sizes that the exposure tool can repeatedly expose on the wafer. The resolution value of present exposure tools often constrains the CD for many advanced IC designs.

In some circuits in which the size of the circuit features approach the optical limits of the lithography process, one or more resolution enhancement techniques can be used to improve the accuracy of the pattern transfer from the layout to the wafer. For example, as the size of integrated circuit features drops to 0.18 μm and below, the features can become smaller than the wavelength of light used to create such features, thereby creating lithographic distortions when printing the features onto the wafer. Resolution enhancement techniques (RETs) can compensate for such lithographic distortions.

A gate trim etch is a RET that allows further reduction of gate widths using etching techniques. In a conventional gate trim etch, the hard mask on the polysilicon gate is “trimmed” to a smaller dimension typically by an anisotropic oxygen plasma etch prior to the gate etch. The polysilicon gates are then formed using a conventional etching process. The polysilicon gates formed in this manner replicate the dimensions of the trimmed photoresist masks, resulting in smaller gate widths.

Problems arise, however, during the gate trim etch process due to asymmetric mechanical stresses in various portions of the patterned hard mask. For example, asymmetrical mechanical stress can arise at portions of the patterned hard mask where field polysilicon regions join gate regions. For example, FIG. 1A shows a patterned hard mask with a desired pattern geometry 100 that includes a gate structure 110, an active area 120, and a first field polysilicon structure 135 and a second field polysilicon structure 145. During conventional fabrication of desired pattern geometry 100, however, the gate trim etch results in structural errors of the hard mask. As shown in FIG. 1B, these errors include areas of necking 113 and line breakage, in particular, at high mechanical stress areas. These problems can result in high leakage current and device failure.

Thus, there is a need to overcome these and other problems of the prior art to provide methods to reduce mechanical stress during a gate trim etch process.

### SUMMARY OF THE INVENTION

According to various embodiments, a method for forming a semiconductor device is provided. The method can include defining at least a plurality of gate structures in a first mask layer using a first reticle and using the first mask layer to replicate the defined plurality of gate structures in a third mask layer. The ends of each of the defined plurality of gate structures can connect to an unpatterned region of the third mask layer. The third mask layer can be etched to reduce a width of each of the defined plurality of gate structure. At least one field polysilicon region can be defined in a second mask layer using a second reticle and the second mask layer can be used to replicate the defined at least one field polysilicon region in the third mask layer.

According to various other embodiments, a method for reducing necking during a gate trim etch is provided. The method can include patterning a first mask to define a plurality of gate structures, wherein each end of the plurality of the gate structures is attached to an unpatterned region. The defined plurality of gate structures can be gate trim etched. A second mask can be patterned to define a field polysilicon structure, wherein the field polysilicon structure is connected to at least one of the plurality of gate structures. The defined plurality of gate structures can be transferred from the first mask and the defined field polysilicon structure from the second mask to a third mask. A polysilicon layer can then be etched using the third mask to form the gate structure and the field polysilicon structure.

According to various other embodiments, a semiconductor device is provided. The semiconductor device can include a plurality of lines defined by a first patterned mask, wherein each line defined by a first patterned mask is gate trim etched. The semiconductor device can also include at least one field polysilicon structure defined by a second patterned mask, wherein the first patterned mask and the second patterned mask form a pattern specific geometry and wherein the second patterned mask is patterned after the first patterned mask has been gate trim etched.

It is to be understood that both the foregoing general description and the following detailed description are exemplary and explanatory only and are not restrictive of the invention, as claimed.

The accompanying drawings, which are incorporated in and constitute a part of this specification, illustrate embodiments of the invention and together with the description, serve to explain the principles of the invention.

### BRIEF DESCRIPTION OF THE DRAWINGS

FIG. 1A depicts a top view of a layout including an exemplary desired pattern geometry in accordance with various embodiments of the present teachings.

FIG. 1B depicts a top view of errors resulting from a conventional gate trim etch.

FIG. 2 depicts a top view of a layout including an exemplary desired pattern geometry in accordance with various embodiments of the present teachings.

FIG. 3A depicts a top view of a resist layer patterned to define gate regions in accordance with various embodiments of the present teachings.

FIG. 3B is a cross sectional side view taken along line A-A of FIG. 3A depicting a patterning step in accordance with various embodiments of the present teachings.

FIG. 3C is a cross sectional side view taken along line A-A of FIG. 3A depicting another patterning step in accordance with various embodiments of the present teachings.

FIG. 3D depicts a top view of a hard mask patterned to define gate regions in accordance with various embodiments of the present teachings.

FIG. 3E is a cross sectional side view taken along line B-B of FIG. 3D depicting a gate trim etch step in accordance with various embodiments of the present teachings.

FIG. 3F is an expanded top view depicting a patterned hard mask including a plurality of gate regions after a gate trim etch in accordance with various embodiments of the present teachings.

FIG. 3G is an expanded top view depicting another hard mask defining field polysilicon regions in accordance with various embodiments of the present teachings.

FIG. 3H is an expanded top view depicting a double patterned hard mask formed in accordance with various embodiments of the present teachings.

FIG. 4A depicts a top view of another layout including an exemplary desired pattern geometry in accordance with various embodiments of the present teachings.

FIG. 4B depicts a method of separating the exemplary desired pattern geometry of FIG. 4A into a first portion and a second portion in accordance with various embodiments of the present teachings.

FIG. 4C is a cross sectional side view taken along line C-C of FIG. 4B depicting a step in a gate trim etch in accordance with various embodiments of the present teachings.

FIG. 4D depicts a top view of a hard mask patterned using a first reticle to define a plurality of gate regions.

FIG. 4E is a cross sectional side view depicting another step in a gate trim etch in accordance with various embodiments of the present teachings.

FIG. 4F is an expanded top view depicting a patterning step to form a field polysilicon portion of a desired structure in accordance with various embodiments of the present teachings.

FIG. 4G is an expanded top view depicting a patterned hard mask formed in accordance with various embodiments of the present teachings.

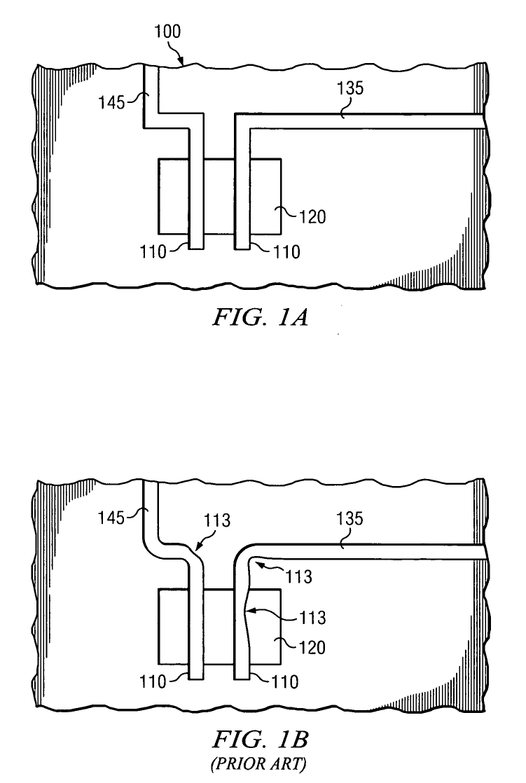

### DESCRIPTION OF THE EMBODIMENTS

Reference will now be made in detail to embodiments, examples of which are illustrated in the accompanying drawings. Wherever possible, the same reference numbers will be used throughout the drawings to refer to the same or like parts.

Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5.

Although reference is made herein to the use of the invention in the manufacture of ICs, it is to be understood that the invention has many other possible applications. For example, it may be employed in the manufacture of integrated optical systems, guidance and detection patterns for magnetic domain memories, liquid crystal display panels, thin-film magnetic heads, etc. Further, one of ordinary skill in the art will appreciate that, in the context of such alternative applications, any use of the term “reticle”, “wafer”, or “die” in this text should be considered as being replaced by the more general terms “mask”, “substrate”, and “target portion”, respectively.

The term “mask,” as used herein, can be broadly interpreted as referring to generic pattern means that can be used to endow an incoming beam with a patterned cross-section, corresponding to a target pattern that is to be created in a target portion of the substrate.

As used herein, the term “pattern specific geometry” means a semiconductor device layout or a portion of a semiconductor device layout that includes at least one portion within an active area, such as, for example, a gate structure, and at least one portion in a field area, such as, for example, a field polysilicon structure.

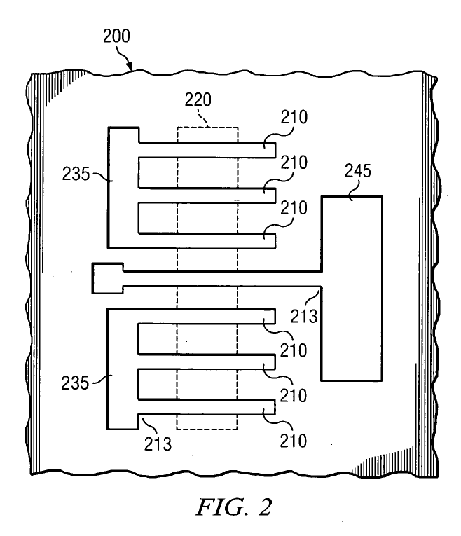

FIGS. 2-4G depict exemplary methods to eliminate high stress areas in a mask during a gate trim etch. High stress areas can include, for example, gate regions that are anchored at only one end. The exemplary methods can include the use of a double pattern layout, for example, separating printing and etching of a pattern specific geometry in the mask into two or more portions. For example, a first portion that defines at least a plurality of gate structures requiring a gate trim etch can be associated with a first reticle. A second portion of the layout can be associated with a second reticle that does not require a gate trim etch, such as, for example a field polysilicon portion. The first portion can be formed first. After the gate trim etch, the second portion can be formed.

FIG. 2 depicts a portion of a layout including a pattern specific geometry 200. Pattern specific geometry can include, for example, a gate portion 210 over an active area 220, and a first field polysilicon portion 235 and a second field polysilicon portion 245. During conventional fabrication, high mechanical stress areas can exist in the mask, for example, at regions 213. According to an exemplary embodiment, a method for reducing the high mechanical stress in pattern specific geometry 200 can include the use of a double pattern layout, such as, for example, dividing pattern specific geometry 200 into two or more portions using two or more reticles. An exemplary method will be described with reference to a gate trim etch. However, one of skill in the art will understand that the exemplary method can be used to reduce mechanical stress in other etching processes.

Referring again to FIG. 2, mechanical stress can be reduced in pattern specific geometry 200 by, for example, separating printing and etching of pattern specific geometry 200 into two portions. For example, gate portion 210 requires a gate trim etch to achieve a desired gate width, but first field polysilicon portion 235 and second field polysilicon portion 245 do not require a gate trim etch. Recognizing this, high mechanical stress areas 113 can be eliminated by patterning gate portion 210 in the mask using a first reticle and then pattering field polysilicon portions 235 and 245 in the mask using a second reticle.

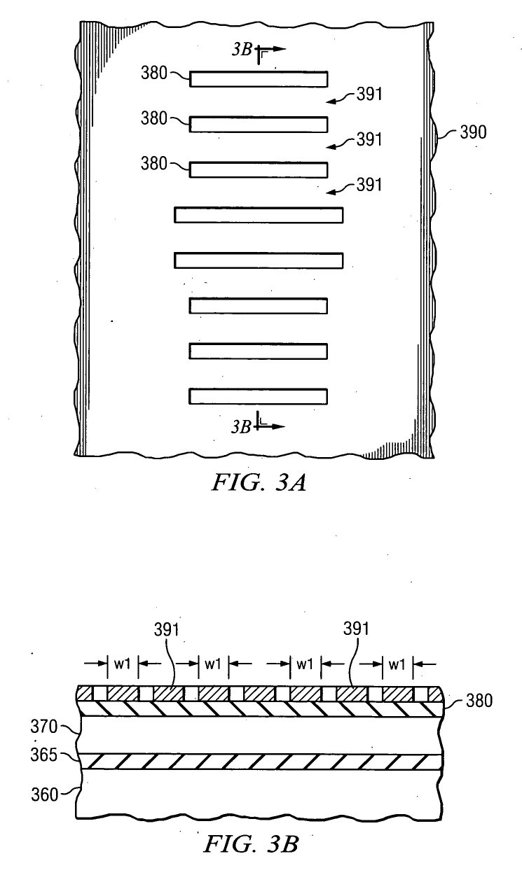

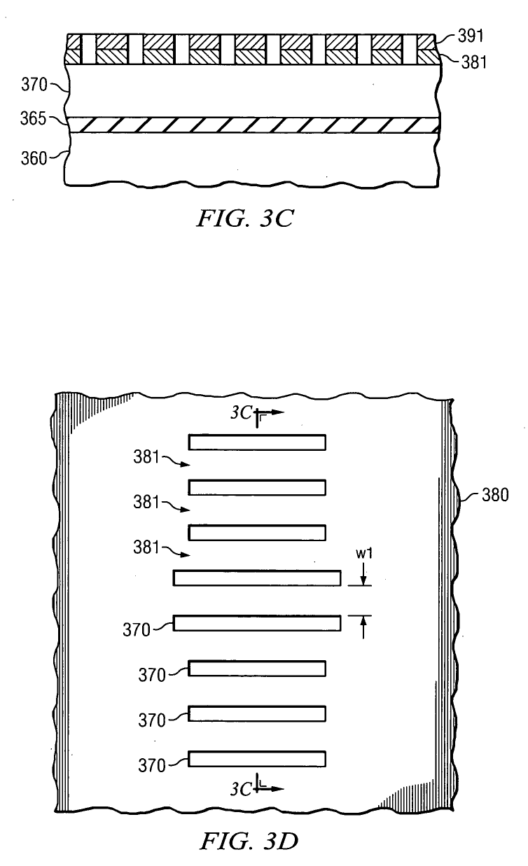

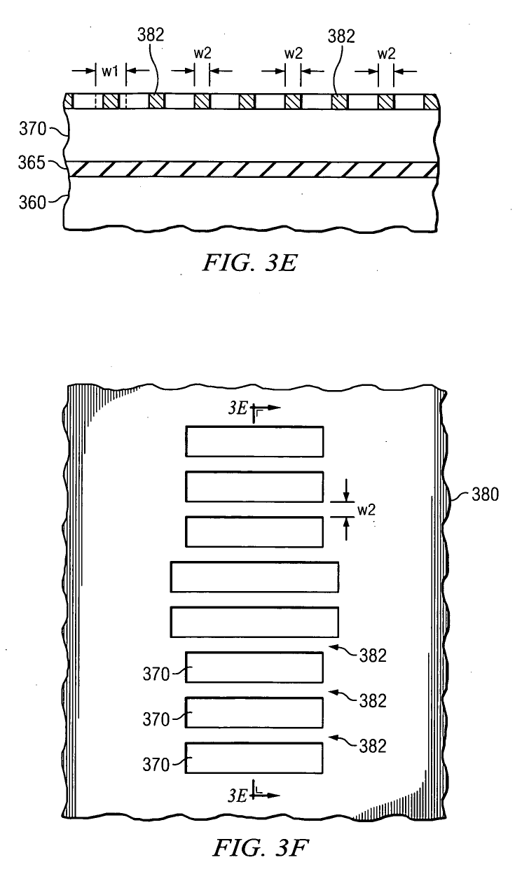

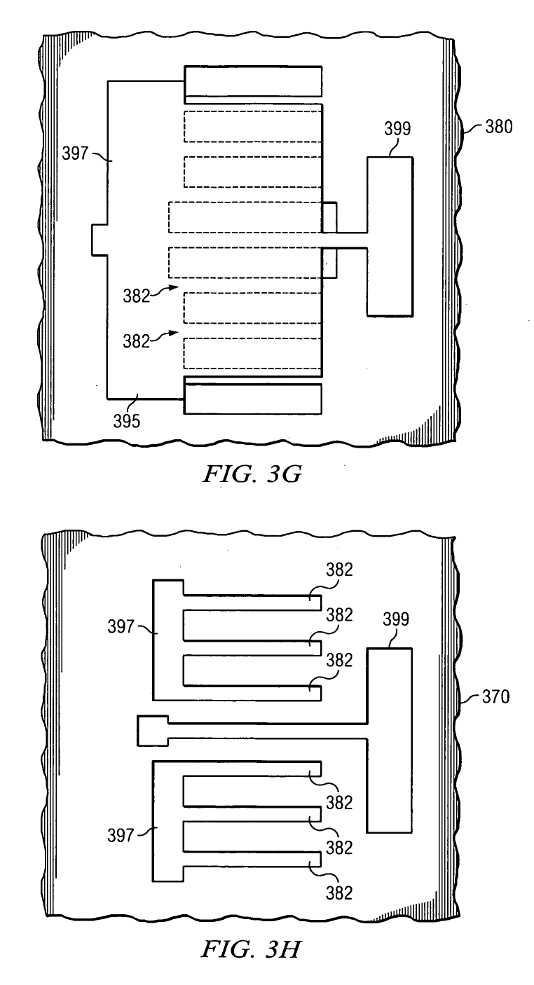

Turning now to the formation of pattern specific geometries, in various embodiments, at least two reticles can be used. According to various embodiments, a first reticle can be tied to a trim etch and a second reticle to a transfer etch. Referring to the top view of FIG. 3A, the first reticle can be used to pattern a first mask layer 390 and first mask layer 390 can be etched to define a plurality of resist gate portions 391. First mask layer 390 can be disposed over a third mask layer 380, portions of which are exposed.

Referring to the partial cross sectional view of FIG. 3B taken along, line A-A of FIG. 3A, a polysilicon layer 370 can be disposed over a gate oxide layer 365. Gate oxide layer 365 can be disposed on a substrate 360. Third mask layer 380, for example, an anti-reflective coating (ARC) layer, can be disposed on polysilicon layer 370. First mask layer 390 (not shown), for example, a photoresist, can be disposed on third mask layer 380. In various embodiments, third mask layer 380 can be a hard mask formed of, for example, SiON. FIG. 3B depicts an intermediate stage of processing in which first mask layer 390 has been patterned to define a plurality of resist gate portions 391 having a width W₁ using the first reticle. In various embodiments, width W₁ can be 65 nm or more.

As shown in FIG. 3C, third mask layer 380 can be etched to form a plurality of mask gate portions 381 that define the gates that correspond, for example, to 210 in FIG. 2. Because resist gate portions 391 are used to pattern third mask layer 380, mask gate portions 381 can have a width W₁. First mask 390, including resist gate portions 391, can then be removed.

FIG. 3D depicts an expanded top view of the resultant structure after removal of first mask 390. Each of the plurality of mask gate portions 381 can have a width W₁. Moreover, each of the plurality of mask gate portions 381 are anchored at both ends to unpatterned areas thereby minimizing stress from unanchored gate ends. This can eliminate mechanical stress that causes bending, breaking, and/or necking of mask gate portion 381, in particular, during the subsequent gate trim etch.

According to various embodiments, third mask layer 380 can be etched to trim the width of mask gate portion 381 to a second width W₂ that is smaller than W₁, as shown in the partial cross sectional view of FIG. 3E, taken along line B-B of FIG. 3D. Mask gate portions 381 can be trimmed using conventional gate trimming methods, such as, for example, plasma etching to form mask gate portions 382 having second width W₂. In various embodiments, width W₂ can be 40 nm or less.

FIG. 3F shows a top down expanded view of mask gate portions 382 having a width W₂. As shown in FIG. 3F, each end of gate portion 382 that defines the gate structure is still attached to the larger unpatterned region.

After forming the first portion of pattern specific geometry 200 by gate trim etching to form mask gate portion 382 having second width W₂, formation of a second portion of pattern specific geometry can begin. The second portion of pattern specific geometry can correspond to, for example, field polysilicon portions 235 and 245 shown in FIG. 2.

If necessary, a cleaning process can first be used to remove residue. Referring to the top view expanded view of FIG. 3G, a second mask layer 395 can be formed on third mask layer 380 and patterned using the second reticle. Second mask layer 395 can be, for example, a bottom anti-reflective coating (BARC) layer. Second mask layer 395 can be patterned and etched to cover gate portions 382 of third mask layer 380, depicted by dotted/dashed lines in FIG. 3G. Second mask layer 395 can be further patterned to define the second portion of the pattern specific geometry, such as, for example, field polysilicon portions 397 and 399 that can correspond, for example, to 235 and 245 shown in FIG. 2, respectively.

Second mask layer 395 including field polysilicon portions 397 and 399, can be used to pattern third mask layer 380. As shown in FIG. 3H, field polysilicon portions 397 and 399 of second mask 395 can be transferred to third mask 380. At this point, third mask 380 can include trimmed gate portions 382 and field polysilicon portions 387 and 389 (corresponding to 397 and 399, respectively). Polysilicon layer 370 can then be etched to form the gate and field polysilicon structures defined by mask 380 and corresponding to, for example, pattern specific geometry 200 shown in FIG. 2.

In the embodiment described above using two reticles, the first reticle can be used to pattern the first portion including gate regions in which the ends of the gate regions are anchored to unpatterned regions and which can be subject to a trim etch. The second reticle can be used to pattern the second portion including field polysilicon regions. One of ordinary skill in the art understands, however, that more than two reticles can be used. Moreover, one of ordinary skill in the art understands that the first portion patterned by the first reticle can include field polysilicon regions and/or that the second portion patterned by the second reticle can include gate regions.

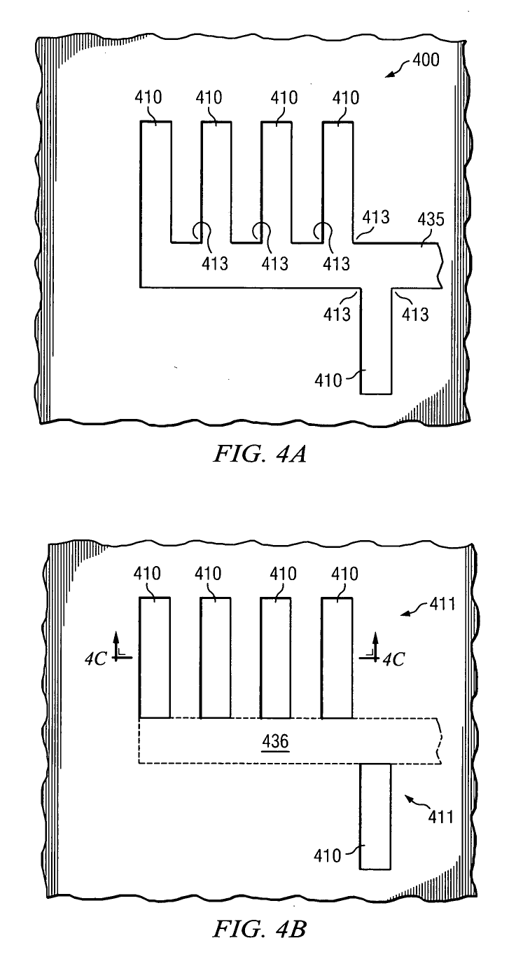

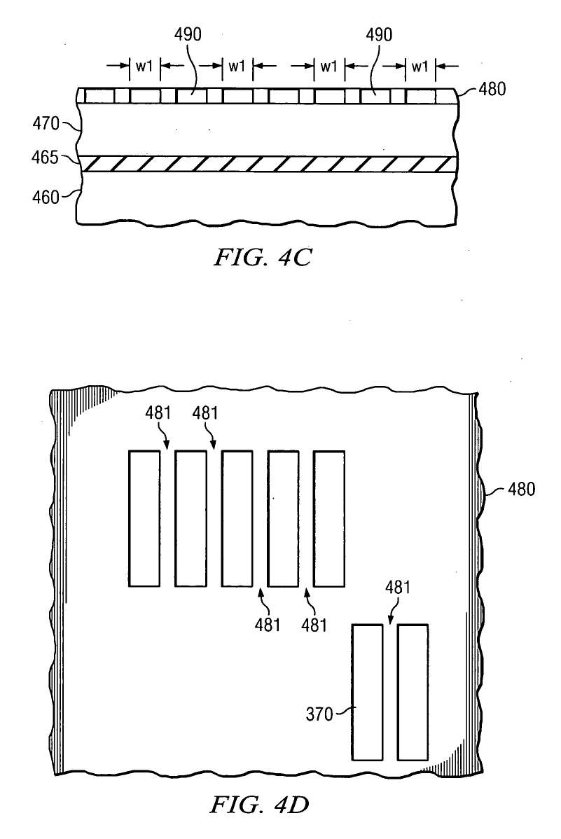

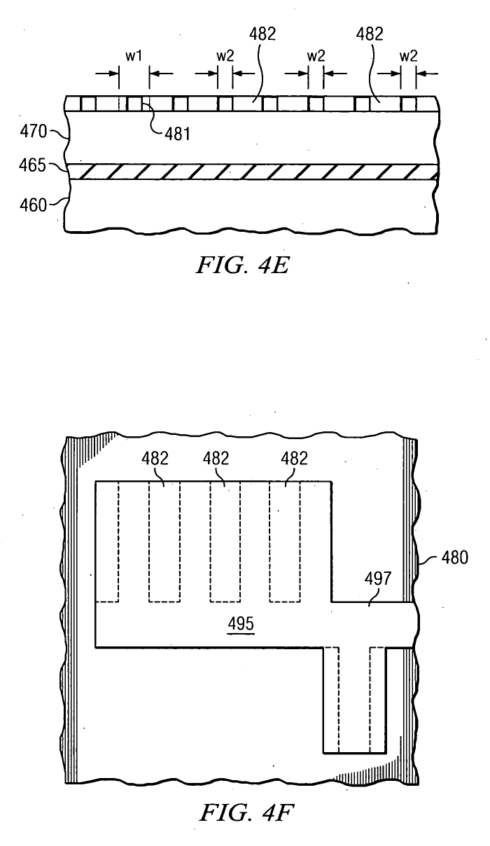

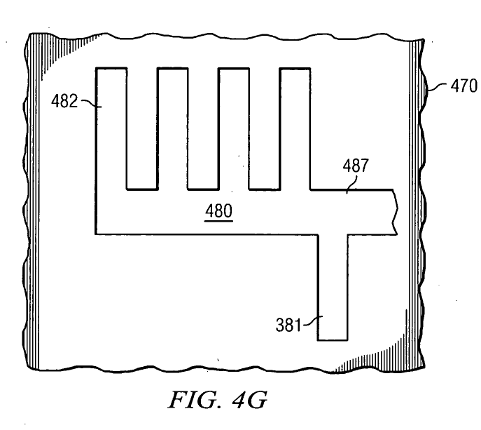

In another exemplary embodiment shown in FIG. 4A, a portion of a layout can include a pattern specific geometry 400 that defines a plurality of gate structures 410 and a field polysilicon structure 435. High mechanical stress areas can cause errors during formation of pattern specific geometry 400 in a mask at, for example, regions 413.

Referring to FIG. 4B, mechanical stress at regions 413 can be reduced in pattern specific geometry 400 by, for example, by separating printing and etching of pattern specific geometry 400 in a hard mask into two or more portions. For example, a first portion 411 can define a plurality of gate structures 410 that requires a gate trim etch to achieve a desired gate width. A second portion 436, represented by the dashed line, can defined field polysilicon structure 435. According to various embodiments, high mechanical stress areas 413 can be eliminated by forming first portion 411 prior to forming second portion 436. In various embodiments, both ends of the gate regions can be anchored during formation of first portion 410.

Fabrication of pattern specific geometry 400 to eliminate high stress areas will now be described with reference to FIGS. 4C-4G. An exemplary method for reducing mechanical stress can form first portion 411 of the hard mask, defining plurality of gate structures 410, using a first reticle. FIG. 4C shows a cross section taken along, for example line C-C of FIG. 4B. A polysilicon layer 470 can be disposed over a gate oxide layer 465. Gate oxide layer 465 can be disposed on a substrate 460. A third mask layer 480, for example, an anti-reflective coating (ARC) layer, can be disposed on polysilicon layer 470. A first mask layer 490, for example, a photoresist, can be disposed on third mask layer 480. FIG. 4C depicts an intermediate stage of processing in which first mask 490 has been patterned to a first gate width W₁ using the first reticle. In various embodiments, width W₁ can be 65 nm or more.

Third mask layer 480 can then be patterned to define a plurality of mask gate portions 481. Because first mask 490 can be used to pattern third mask layer 480, mask gate portions 481 can have a width W₁. Referring now to the expanded top view of FIG. 4D, third mask 480 can include mask gate portions 481 that correspond to first portion 411 of pattern specific geometry 400 shown in FIG. 4B. As shown in FIG. 4D, the ends of mask gate portions 481 are each anchored to a larger unpatterned region. This can eliminate stress that causes bending, breaking, and/or necking of mask gate portion 481, in particular, during the gate trim etch.

Mask gate portions 481 can then be trimmed to a second gate width W₂ that is smaller than W₁, as shown in FIG. 4E. Mask gate portions 481 can be trimmed using conventional gate trimming methods, such as, for example, a plasma etch to form mask gate portions 482 having width W₂. In various embodiments, width W₂ can be 40 nm or less.

Upon completion of the gate trim etch to form first portion 411 defining plurality of gate structures 410, fabrication of second portion 436 using a second reticle can begin. FIG. 4F shows an expanded top view of a second mask layer 495 that can be formed on third mask layer 480. Second mask layer 495 can be, for example, a BARC. As shown in FIG. 4F, second mask layer 495 can cover mask gate portions 482. A field polysilicon portion 497 can be patterned in second mask 495 that corresponds to field polysilicon 436 shown in FIG. 4B.

Second mask layer 495 defining field polysilicon portion 497 can be used to pattern third mask layer 480. As shown in FIG. 4G, field polysilicon portion 497 of second mask 495 can be transferred to third mask 480 by, for example, conventional methods for etching an ARC layer. After removing second mask 495, third mask 480 can include trimmed gate portions 482 and a field polysilicon portion . 487. Using third mask 480, polysilicon layer 460 can then be etched to form the gate and field polysilicon structures defined by pattern specific geometry 400. The resultant structure includes a patterned polysilicon layer 460 that resembles pattern specific geometry 400 shown in FIG. 4A.

In the embodiment described above, the first reticle can be used to pattern the first portion including gate regions in which the ends of the gate regions are anchored to unpatterned regions during the gate trim etch. The second reticle can be used to pattern the second portion including field polysilicon regions. One of ordinary skill in the art understands, however, that more than two reticles can be used. Moreover, one of ordinary skill in the art understands that the pattern defined by the first reticle is not limited to gate regions and can include field polysilicon regions. Further, the pattern defined by the second reticle is not limited to field polysilicon regions and can include gate regions.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A method for forming a semiconductor device comprising:
defining at least a plurality of gate structures in a first mask layer using a first reticle;
using the first mask layer to replicate the defined plurality of gate structures in a third mask layer, wherein ends of each of the defined plurality of gate structures connect to an unpatterned region of the third mask layer;
etching the third mask layer to reduce a width of each of the defined plurality of gate structures;
defining at least one field polysilicon region in a second mask layer using a second reticle; and
using the second mask layer to replicate the defined at least one field polysilicon region in the third mask layer.

2. The method of claim 1 further comprising etching a polysilicon layer disposed below the third mask layer to form the plurality of gate structures and the at least one field polysilicon region.

3. The method of claim 1, wherein at least one of the first mask layer and the second mask layer comprise a photoresist.

4. The method of claim 1, wherein the third mask layer comprises an anti-reflection coating (ARC).

5. The method of claim 1, wherein the second mask comprises a bottom anti-reflection coating (BARC).

6. The method of claim 1, wherein the step of etching the third mask layer to reduce a width of each of the defined plurality of gate structures comprises reducing the width each of the defined plurality of gate structures to 40 nm or less.

7. The method of claim 1, wherein the step of etching the third mask layer to reduce a width of each of the defined plurality of gate structures comprises plasma etching.

8. The method of claim 1, wherein the step of defining at least a plurality of gate structures in a first mask layer using a first reticle further comprises defining a field polysilicon structure.

9. A method for reducing necking during a gate trim etch comprising:
patterning a first mask to define a plurality of gate structures, wherein each end of the plurality of the gate structures is attached to an unpatterned region;
gate trim etching the defined plurality of gate structures;
patterning a second mask to define a field polysilicon structure, wherein the field polysilicon structure is connected to at least one of the plurality of gate structures; and
transferring the defined plurality of gate structures from the first mask and the defined field polysilicon structure from the second mask to a third mask; and
etching a polysilicon layer using the third mask to form the gate structure and the field polysilicon structure.

10. The method of claim 9, wherein the third mask comprises an inorganic anti-reflection coating (IARC).

11. The method of claim 9, wherein at least one of the first and the second mask comprises a photoresist.

12. The method of claim 9, wherein the step of gate trim etching the first width to a second width comprises an isotropic etch.

13. The method of claim 9, wherein the step of gate trim etching the first width to a second width results in the second width being 40 nm or less.

14. A semiconductor device comprising:
a plurality of lines defined by a first patterned mask, wherein each line defined by a first patterned mask is gate trim etched; and
at least one field polysilicon structure defined by a second patterned mask,
wherein the first patterned mask and the second patterned mask form a pattern specific geometry and
wherein the second patterned mask is patterned after the first patterned mask has been gate trim etched.

15. The semiconductor device of claim 14, wherein the first patterned mask comprises a photoresist layer.

16. The semiconductor device of claim 14, further comprising an IARC layer underlying the first patterned mask and the second patterned mask.

17. The semiconductor device of claim 16, further comprising a polysilicon layer underlying the IARC layer.

18. The semiconductor device of claim 14, wherein each of the plurality of gate structures has a gate width 40 nm or less.

19. The semiconductor device of claim 14, further comprising an etched polysilicon layer comprising the plurality of gate structures and the at least one field polysilicon structure.
